(19) United States
(12) Patent Application Publication
(10) Pub. No.: US 2009/0325360 A1
(43) Pub. Date: Dec. 31, 2009

(54) Method of Forming Trench of Semiconductor Device

(75) Inventor: Yong Hyun Lim, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Gyeonggi-do (KR)

(21) Appl. No.: 12/492,806

(22) Filed: Jun. 26, 2009

(30) Foreign Application Priority Data
Jun. 27, 2008 (KR) KR 10-2008-61655

(51) Int. Cl. H01L 21/28; H01L 21/762

(52) U.S. Cl. 438/424; 438/585; 257/E21.19; 257/E21.546

(57) ABSTRACT

The invention relates to a method of forming a trench of a semiconductor device. According to the method, a semiconductor substrate including a first region and a second region is provided. A gate insulating layer, a gate conductive layer, and a hard mask pattern are formed over the semiconductor substrate. First trenches are simultaneously formed in respective isolation areas of the first region and the second region by etching the gate conductive layer, the gate insulating layer, and the semiconductor substrate using an etch process employing the hard mask pattern. A second trench having a recess is formed on a bottom of the first trench formed in the second region. The recess is formed by widening the first trench by further etching the first trench.

### CROSS-REFERENCES TO RELATED APPLICATIONS

Priority to Korean patent application number 10-2008-0061655, filed on Jun. 27, 2008, the disclosure of which is incorporated by reference in its entirety, is claimed.

### BACKGROUND OF THE INVENTION

The invention relates to a method of forming a trench of a semiconductor device and, more particularly, to a method of forming a trench of a semiconductor device, in which isolation layers for isolating high-voltage elements are formed.

In general, a semiconductor device formed in a silicon wafer includes isolation layers formed in an isolation area. These isolation layers are located between active areas in which semiconductor elements are formed, and electrically isolate the respective semiconductor elements. Thus, the isolation layer is an important factor in determining the characteristics of the semiconductor elements.

A shallow trench isolation (STI) method of forming isolation layers is described below. First, a gate insulating layer and a gate conductive layer are formed over a semiconductor substrate. A hard mask pattern is formed on the gate conductive layer. The gate conductive layer, the gate insulating layer, and the semiconductor substrate above the isolation area are etched to a specific depth using an etch process employing the hard mask pattern, thus forming trenches. The trenches are gap-filled with an insulating layer (for example, an oxide layer) to complete formation of the isolation layers.

However, in line with high performance characteristics and the high degree of integration of semiconductor elements, a gap between the semiconductor elements is gradually reduced in size. In particular, a channel area having a high channel voltage is formed in high-voltage elements to which a relatively high voltage is applied, as compared to other semiconductor elements. If the gap between the high-voltage elements is gradually reduced in size, neighboring channel areas are not sufficiently isolated by the isolation layers and become electrically connected to each other, so that the leakage current may be generated.

Such generation of the leakage current may deteriorate the performance of semiconductor elements. Accordingly, it is necessary to form isolation layers with high performance, which can sufficiently isolate the channel areas of neighboring high-voltage elements.

### BRIEF SUMMARY OF THE INVENTION

The invention is directed to a method of forming a trench of a semiconductor device, in which a recess is formed under isolation layers, which recess isolates neighboring high-voltage elements from each other, in order to increase the size of a gap between neighboring channel areas, wherein in a trench formation process of a low-voltage element area, an upper portion of an area in which the recess of a high-voltage element area will be formed is etched, and trenches are formed in the high-voltage element area, thereby not necessitating an additional process of forming a recess under the isolation layers of the high-voltage element area.

In accordance with a method of forming a trench of a semiconductor device according to an aspect of the invention, a semiconductor substrate defining a first region and a second region is provided. Semiconductor elements to be formed in the second region are to be applied with a voltage higher than that to be applied to semiconductor elements formed in the first region. A gate insulating layer, a gate conductive layer, and a hard mask layer are formed over the semiconductor substrate. A first photoresist pattern is formed on the hard mask layer. A gate pattern is formed in the first region and a first trench, which is narrower than the isolation area, is formed in the second region, by etching the hard mask layer, the gate conductive layer, the gate insulating layer, and the semiconductor substrate in respective isolation areas of the first and second regions using an etch process employing the first photoresist pattern. The first photoresist pattern is removed. A second photoresist pattern through which a top surface of the isolation area of the second region is opened is formed on the hard mask layer. A second trench is formed in the isolation area of the second region using an etch process employing the second photoresist pattern. A recess is formed on a bottom of the second trench by further etching the first trench.

The first trench is preferably narrower than a top of the second trench. A bottom surface of the first trench is preferably 500 angstrom to 1500 angstrom lower than the gate insulating layer. A depth of the recess area preferably ranges from 500 angstrom to 1500 angstrom. The semiconductor elements formed in the second region are preferably wider than the semiconductor elements formed in the first region. The isolation area of the second region is preferably wider than the isolation area of the first region. The first photoresist pattern is preferably formed from a photoresist for ArF. The second photoresist pattern is preferably formed from a photoresist for KrF. The first region preferably includes a memory cell area of a flash memory device. The second region preferably includes a peripheral circuit area of a flash memory device.

In accordance with a method of forming a trench of a semiconductor device according to another aspect of the invention, a semiconductor substrate including a first region and a second region is provided. A gate insulating layer, a gate conductive layer, and a hard mask pattern are formed over the semiconductor substrate. First trenches are simultaneously formed in isolation areas of the first region and the second region by etching the gate conductive layer, the gate insulating layer, and the semiconductor substrate using an etch process employing the hard mask pattern. A second trench having a recess is formed on a bottom of the first trench formed in the second region. The recess is formed by widening the first trench by further etching the first trench.

### BRIEF DESCRIPTION OF THE DRAWINGS

FIGS. 1A to 1H are sectional views illustrating a method of forming a trench of a semiconductor device according to the invention; and

FIG. 2 is an SEM photograph illustrating the method of forming a trench of a semiconductor device according to the invention.

### DESCRIPTION OF SPECIFIC EMBODIMENTS

Hereinafter, the invention is described in detail in connection with a specific embodiment with reference to the accompanying drawings. The described embodiment is provided to complete the disclosure of the invention and to allow those having ordinary skill in the art to understand the scope of the invention. When it is said that any part, such as a layer, film, area, or plate, is positioned on another part, it means the part is directly on the other part or above the other part with at least one intermediate part. To clarify multiple layers and regions, the thickness of the layers is enlarged in the drawings.

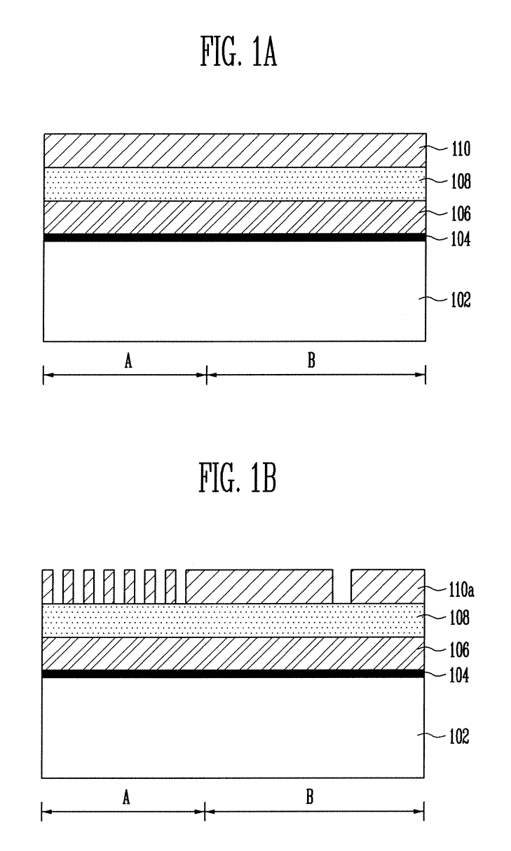

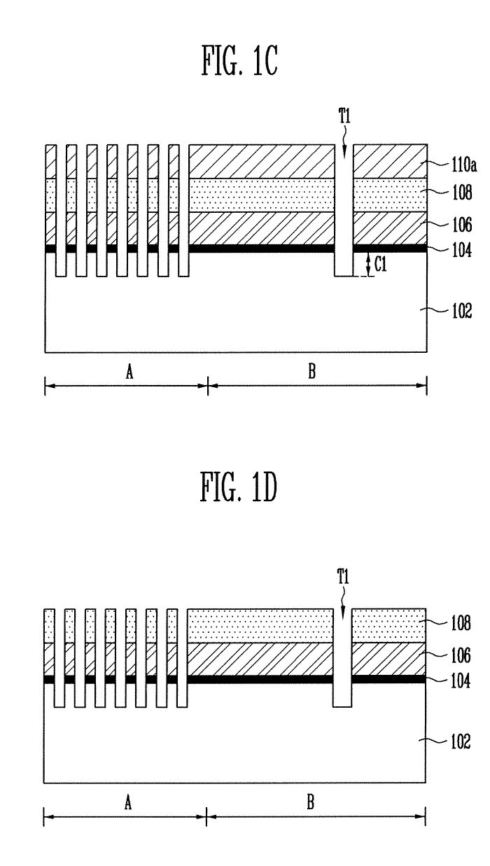

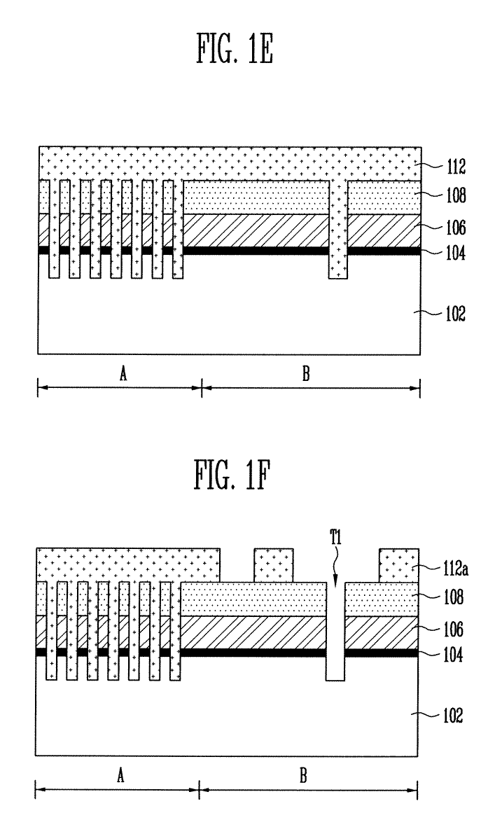

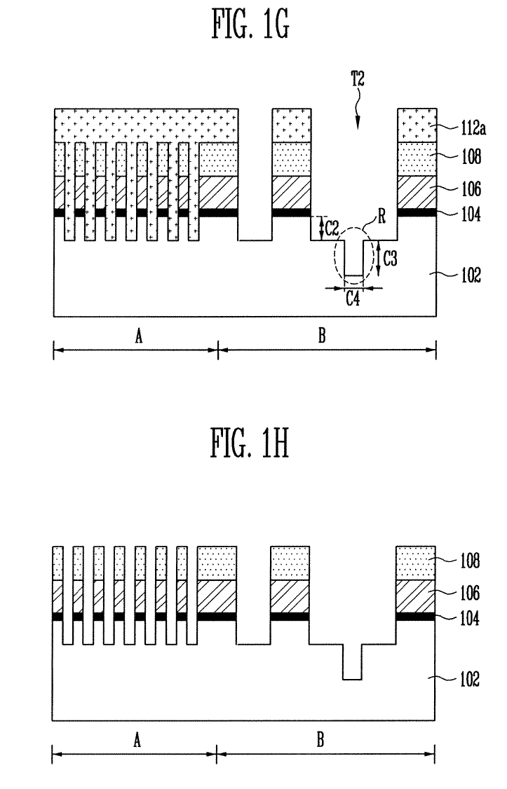

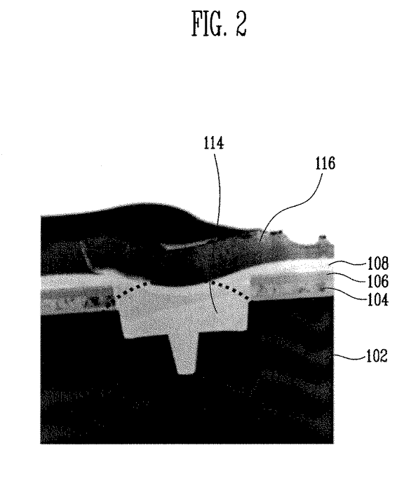

FIGS. 1A to 1H are sectional views illustrating a method of forming a trench of a semiconductor device according to the invention.

Referring to FIG. 1A, there is provided a semiconductor substrate 102 defining a first region A and a second region B, each of which defines a respective isolation area. Gates of semiconductor elements to be formed in the second region B are to be applied with voltage much higher than that of semiconductor elements to be formed in the first region A. For example, in the case of flash memory devices, the first region A may be a memory cell area in which a memory cells are formed, and the second region B may be a peripheral circuit area for driving the memory cells (in particular, the peripheral circuit area in which a high-voltage element, e.g., a high-voltage NMOS transistor, is formed). The high-voltage element to be formed in the second region B has the same width as the gate and the isolation area, which are wider than the semiconductor elements to be formed in the first region A.

A screen oxide layer (not shown) is formed on the semiconductor substrate 102. A well ion implantation process and a threshold voltage ion implantation process are performed on the semiconductor substrate 102. The well ion implantation process is performed to form a well area in the semiconductor substrate 102, and the threshold voltage ion implantation process is performed to control the threshold voltage of semiconductor elements such as transistors. The screen oxide layer (not shown) prevents a surface of the semiconductor substrate 102 from being damaged at the time of the well ion implantation process or the threshold voltage ion implantation process.

Next, the screen oxide layer (not shown) is removed. A gate insulating layer 104 is formed on the semiconductor substrate 102. The gate insulating layer 104 preferably comprises an oxide layer. For example, in the case of the fabrication process of flash memory devices, the gate insulating layer 104 formed in the first region A may be a tunnel dielectric layer of the flash memory device. The tunnel dielectric layer can have electrons pass therethrough by Fowler/Nordheim (F/N) tunneling. Meanwhile, although not shown in the drawings, the gate insulating layer 104 formed in the second region B may be thicker than the gate insulating layer 104 formed in the first region A.

A gate conductive layer 106 is formed on the gate insulating layer 104. The gate conductive layer 106 is formed from a polysilicon layer. For example, in the case of the fabrication process of flash memory devices, the gate conductive layer 106 may be a conductive layer for a floating gate of the flash memory device. In this case, the gate conductive layer 106 may store or discharge charges. Accordingly, at the time of a program operation, electrons of the channel area of the semiconductor substrate 102 can pass through the gate insulating layer 104 and then accumulate in the gate conductive layer 106. At the time of an erase operation, electrons stored in the gate conductive layer 106 can pass through the gate insulating layer 104 and be then discharged to the semiconductor substrate 102.

A hard mask layer 108, which is used in a gate etch process, is formed over the gate conductive layer 106. The hard mask layer 108 is preferably formed from a material layer (for example, a nitride layer) having an etch selectivity different from that of the gate conductive layer 106. A buffer layer formed from an oxide layer is preferably further formed between the gate conductive layer 106 and the hard mask layer 108.

A first photoresist film 110 is formed on the hard mask layer 108. The first photoresist film 112 is preferably formed from a photoresist film for ArF such that it is suitable for defining the isolation area of the first region A having a micro width as compared with the isolation area of the second region B.

Referring to FIG. 1B, an exposure and development process is performed on the first photoresist film 110, thereby forming first photoresist patterns 110a. The first photoresist patterns 110a are formed in such a way as to open a top surface of the isolation area of the first region A and a top surface of the isolation area of the second region B. In particular, a width in which the top surface of the isolation area of the second region B is opened is narrower than that of the isolation area of the second region B.

Referring to FIG. 1C, the hard mask layer 108, the gate conductive layer 106, and the gate insulating layer 104, which are formed over the respective isolation areas of the first region A and the second region B, are etched by an etch process employing the first photoresist patterns 110a, to form patterns. A part of the semiconductor substrate 102 is etched to form trenches. Consequently, the top surface of the isolation area is etched and therefore gate patterns are formed in the first region A while the trenches are formed therein.

A part of the top surface of the isolation area is etched and therefore a first trench T1 having a width narrower than that of the isolation area is formed in the second region B. Here, a depth in which the first trench T1 is formed is decided so that a depth difference C1 between the gate insulating layer 104 and a bottom of the first trench T1 illustratively becomes 500 angstrom to 1500 angstrom.

Referring to FIG. 1D, the first photoresist patterns 110a are removed. The first photoresist patterns 110a are preferably removed using a typical photoresist strip process.

Referring to FIG. 1E, a second photoresist film 112 is formed on the entire surface including the semiconductor substrate 102. The second photoresist film 112 is preferably formed from a photoresist film for KrF such that it is suitable for defining the isolation area of the second region B, which is wider than the isolation area of the first region A.

Referring to FIG. 1F, an exposure and etch process is performed on the second photoresist film 112 to form second photoresist patterns 112a. The second photoresist patterns 112a are formed to open only a top surface of the isolation area of the second region B, so that an aperture of the first trench T1 is exposed through the second photoresist patterns 112a.

Referring to FIG. 1G, the hard mask layer 108, the gate conductive layer 106, and the gate insulating layer 104 on the isolation area of the second region B are etched using an etch process employing the second photoresist patterns 112a, thus forming patterns. A second trench T2 is formed by etching a part of the semiconductor substrate 102. The top of the second trench T2 is wider than the first trench T1, and corresponds to the width of the isolation area. Here, a recess R is formed on the bottom of the second trench T2 by further etching the first trench T1. A depth C3 of the recess R is preferably 500 angstrom to 1500 angstrom.

The recess R increases a distance between the channel areas of neighboring high-voltage elements by as much as twice the depth C3 of the recess R and the sum of a width C4 of the recess R, so that it can increase the leakage current from occurring in the high-voltage elements.

Further, if a recess is formed according to the invention, a photoresist film formation process and an etch process for forming the recess need not be additionally performed. Thus, typically, in order to selectively form a recess only at the bottom a trench of the second region, a photoresist pattern through which a top surface of the isolation area of the first region is opened is first formed, and the trench is formed in the first region using an etch process employing the photoresist pattern. After the photoresist pattern is removed, another photoresist pattern through which a top surface of the isolation area of the second region is opened is formed, and the trench is formed in the second region using an etch process employing another photoresist pattern. Next, still another photoresist pattern through which a part of the trench formed in the second region is opened is formed, and a recess is formed on the bottom of the trench formed in the second region using an etch process employing the still another photoresist pattern. Accordingly, the photoresist pattern formation process and the etch process have to be performed in three steps.

However, the invention employs a process of forming the first trench T1 in the isolation area of the second region B through the etch process of forming the trench in the first region A, and forming the recess R at the bottom of the trench of the second region B through the etch process of forming the trench in the second region B. Accordingly, each of the photoresist pattern formation process and the etch process can be performed in two steps.

Referring to FIG. 1H, the second photoresist patterns 112a are removed. Referring to FIG. 2, a first insulating layer 114 and a second insulating layer 116 are formed over the semiconductor substrate 102 including the second trench T2, thereby gap-filling the second trench T2 with the first insulating layer 114 and the second insulating layer 116. A polishing process is performed on the insulating layers 114, 116 in order to form an isolation layer. The isolation layer formed as described above has the recess formed at its bottom. Accordingly, a distance between the channel areas of neighboring high-voltage elements can be increased, and the occurrence of the leakage current in the high-voltage elements can be prohibited.

In accordance with the method of forming a trench of a semiconductor device according to the invention, a recess is formed on the bottom of an isolation layer of a high-voltage element area. Accordingly, the occurrence of leakage current can be prevented. Further, since it is not necessary to perform an additional process of forming a recess at the bottom of an isolation layer, process efficiency can be increased.

The embodiment disclosed herein has been described to allow a person skilled in the art to easily implement the invention. Therefore, the scope of the invention is not limited by or to the embodiment as described above, and should be construed to be defined only by the appended claims and their equivalents.

What is claimed is:

1. A method of forming a trench of a semiconductor device, the method comprising:
providing a semiconductor substrate having a first region and a second region;
forming a gate insulating layer, a gate conductive layer, and a hard mask layer over the semiconductor substrate;
forming a first photoresist pattern on the hard mask layer;
etching the hard mask layer, the gate conductive layer, the insulating layer, and the semiconductor substrate to form first trenches using the first photoresist pattern as a mask;
removing the first photoresist pattern;
forming a second photoresist pattern over the hard mask layer including the first trench, wherein the first trench of the first region is covered by the second photoresist pattern; and
etching the hard mask layer, the gate conductive layer, the insulating layer, and the semiconductor substrate of the second region to form a second trench using the second photoresist pattern as a mask, wherein the first trench of the second region is further etched during the forming the second trench, and a width of the second trench of the second region is wider than that of the first trench of the second region.

2. The method of claim 1, wherein the first trench and the second trench of the second region is a T shape trench.

3. The method of claim 3, wherein the trench is a dual damascene structure,

4. The method of claim 1 further comprising:
forming a third trench in the second region during forming the second trench.

5. The method of claim 1, wherein a bottom surface of the first trench is lower by 500 angstrom to 1500 angstrom than the gate insulating layer.

6. The method of claim 1 further comprising:
forming isolation structures to fill an insulating material in the first trench of the first region and in the first and second trenches of the second region.

7. The method of claim 1, wherein the first photoresist pattern is formed from a photoresist for ArF.

8. The method of claim 1, wherein the second photoresist pattern is formed from a photoresist for KrF.

9. The method of claim 1, wherein the first region comprises a memory cell area of a flash memory device.

10. The method of claim 1, wherein the second region comprises a peripheral circuit area of a flash memory device.

11. A method of forming a trench of a semiconductor device, the method comprising:
providing a semiconductor substrate defining a first region and a second region;
forming a gate insulating layer, a gate conductive layer, and a hard mask pattern over the semiconductor substrate;
simultaneously forming first trenches in respective isolation areas of the first region and the second region by etching the gate conductive layer, the gate insulating layer, and the semiconductor substrate using an etch process employing the hard mask pattern; and
forming a second trench in the second region,
wherein the first trench is further etched during the forming the second trench, and a width of the second trench of the second region is wider than that of the first trench of the second region.

12. The method of claim 11, wherein the first trench and the second trench of the second region is a T shape trench.

13. The method of claim 12, wherein the trench is a dual damascene structure,

14. The method of claim 11 further comprising:
forming a third trench in the second region during forming the second trench

15. The method of claim 11, wherein a bottom surface of the first trench is lower by 500 angstrom to 1500 angstrom than the gate insulating layer.

16. The method of claim 11 further comprising:
forming isolation structures to fill an insulating material in the first trench of the first region and in the first and second trenches of the second region.

17. The method of claim 11, wherein the first photoresist pattern is formed from a photoresist for ArF.

18. The method of claim 11, wherein the second photoresist pattern is formed from a photoresist for KrF.

19. The method of claim 11, wherein the first region comprises a memory cell area of a flash memory device.

20. The method of claim 11, wherein the second region comprises a peripheral circuit area of a flash memory device.
